(19) United States
(12) Patent Application Publication
(10) Pub. No.: US 2022/0095475 A1
(43) Pub. Date: Mar. 24, 2022

(54) Modular and Portable Data Center

(71) Applicant: Axellio Inc., Colorado Springs, CO (US)

(72) Inventors: Bo David Gustavsson, Monument, CO (US); Grant Carlson, Florissant, CO (US); Aaron Danis, Colorado Springs, CO (US); Duncan Stewart, Colorado Springs, CO (US)

(21) Appl. No.: 17/483,407

(22) Filed: Sep. 23, 2021

Related U.S. Application Data
(60) Provisional application No. 63/082,830, filed on Sep. 24, 2020.

(51) Int. Cl. H05K 7/18; H05K 7/20; H05K 7/14

(52) U.S. Cl. CPC H05K 7/18; H05K 7/1492; H05K 7/1489; H05K 7/20736

(57) ABSTRACT

Novel tools and techniques are provided for implementing a modular and portable data center, and, in particular embodiments, to methods, systems, and apparatuses for implementing a modular and portable data center that fits within a carry-on suitcase. In various embodiments, an apparatus for providing a modular and portable data center might comprise an external case. The external case might have dimensions that comply with commercial carry-on suitcase minimum dimensions. These dimensions might be 9 inches by 14 inches by 22 inches. The external case might have at least two datacenter grade servers contained within the external case, a fan subassembly contained within the external case to cool the at least two datacenter grade servers contained within the external case, and a power subassembly contained within the external case and configured to provide power to the at least two datacenter grade servers and the fan subassembly.

### CROSS-REFERENCES TO RELATED APPLICATIONS

This application claims priority to U.S. Patent Application Ser. No. 63/082,830 (the “830 application”), filed Sep. 24, 2020 by Bo David Gustaysson et al. (attorney docket no. 1193.02PR), entitled, “Modular and Portable Data Center,” the disclosure of which is incorporated herein by reference in its entirety for all purposes.

### COPYRIGHT STATEMENT

A portion of the disclosure of this patent document contains material that is subject to copyright protection. The copyright owner has no objection to the facsimile reproduction by anyone of the patent document or the patent disclosure as it appears in the Patent and Trademark Office patent file or records, but otherwise reserves all copyright rights whatsoever.

### FIELD

The present disclosure relates, in general, to methods, systems, and apparatus for implementing a modular and portable data center, and, in particular embodiments, to methods, systems, and apparatuses for implementing a modular and portable data center that fits within a carry-on suitcase.

### BACKGROUND

Conventional data centers are contained in large buildings such as warehouses. These data centers are industrial scale operations including multiple racks that are designed to house servers, networking devices, cables, and other data center computing equipment. These data centers provide critical computing operations including storage, processing, or distribution of large amounts of data. Because of the industrial scale of data centers, it difficult to provide the real-time computing capabilities of data centers in remote locations.

Hence, there is a need for more robust and scalable solutions for implementing a modular and portable data center, and, in particular embodiments, to methods, systems, and apparatuses for implementing a modular and portable data center that fits within a carry-on suitcase.

### BRIEF DESCRIPTION OF THE DRAWINGS

A further understanding of the nature and advantages of particular embodiments may be realized by reference to the remaining portions of the specification and the drawings, in which like reference numerals are used to refer to similar components. In some instances, a sub-label is associated with a reference numeral to denote one of multiple similar components. When reference is made to a reference numeral without specification to an existing sub-label, it is intended to refer to all such multiple similar components.

FIG. 1 is a perspective view of a modular and portable data center, in accordance with various embodiments, in accordance with various embodiments.

FIG. 2 is a perspective view of a modular and portable data center with a first end of an external case removed, in accordance with various embodiments.

FIG. 3 is a perspective view of an internal case of a modular and portable data center, in accordance with various embodiments.

FIGS. 4A-4C are schematic diagrams illustrating perspective views for a modular and portable data center with one or more datacenter grade server modules removed, in accordance with various embodiments.

FIG. 5 is a perspective view of a modular and portable data center with a fan subassembly, in accordance with various embodiments.

FIG. 6 is a perspective view of a modular and portable data center with a power subassembly removed, in accordance with various embodiments.

FIG. 7 is a schematic diagram illustrating a system for controlling and distributing power in a modular and portable data center, in accordance with various embodiments.

FIGS. 8A and 8B are schematic diagrams of a system for controlling and distributing one or more signals between one or more components in a modular and portable data center, in accordance with various embodiments.

FIG. 9 is a schematic diagram illustrating a system for implementing a cluster of modular and portable data centers, in accordance with various embodiments.

FIG. 10 is a flow diagram illustrating a method for making a modular and portable data center, in accordance with various embodiments.

FIG. 11 is a block diagram illustrating an exemplary computer or system hardware architecture, in accordance with various embodiments.

FIG. 12 is a block diagram illustrating a networked system of computers, computing systems, or system hardware architecture, which can be used in accordance with various embodiments.

### DETAILED DESCRIPTION OF CERTAIN EMBODIMENTS

Overview

Various embodiments provide tools and techniques for implementing a modular and portable data center, and, in particular embodiments, to methods, systems, and apparatuses for implementing a modular and portable data center that fits within a carry-on suitcase.

In various embodiments, an apparatus for providing a modular and portable data center might comprise an external case. The external case might have dimensions that comply with commercial carry-on suitcase minimum dimensions. These dimensions might be 9 inches by 14 inches by 22 inches. The external case might have at least two datacenter grade servers contained within the external case, a fan subassembly contained within the external case to cool the at least two datacenter grade servers contained within the external case, and a power subassembly contained within the external case and configured to provide power to the at least two datacenter grade servers and the fan subassembly.

The at least two datacenter grade servers might each comprise the ability to operate at least 24-core computer processing units (“CPUs”). The external case might further comprise one or more storage modules for storing at least 512 GB of RAM and at least 8 TB of NVMe storage. The external case might further contain at least one full height, full-length (“FHFL”) double-wide graphics processing unit (“GPU”) and might also contain at least two half-height, half-length (“HHHL”) add-in cards.

Several advantages are realized by providing a portable and modular data center. For example, by providing a portable and modular data center, this pushes more computing power to the tactical edge. A portable and modular data center is a field unit that can implement advanced analytics to provide real-time answers to users in the field instead of users having to rely on a centralized industrial-sized data processing center. Further, by providing a portable and modular data center that conforms with commercial airline carry-on restrictions, the portable and modular data center can be taken almost anywhere a data center is needed. For example several commercial uses for the portable and modular data center include emergency response to natural disasters, real-time weather monitoring, remote oil & gas exploration and production, and a dramatic space-saving opportunity for high-performance computing centers. Additionally, because the portable and modular data center can be taken on commercial airline flights as a carry-on, the risk of the modular and portable data center being damaged in the cargo hold of an airplane is eliminated. These and other aspects of the modular and portable data center are described in greater detail with respect to the figures.

The following detailed description illustrates a few exemplary embodiments in further detail to enable one of skill in the art to practice such embodiments. The described examples are provided for illustrative purposes and are not intended to limit the scope of the invention.

In the following description, for the purposes of explanation, numerous specific details are set forth in order to provide a thorough understanding of the described embodiments. It will be apparent to one skilled in the art, however, that other embodiments of the present invention may be practiced without some of these specific details. In other instances, certain structures and devices are shown in block diagram form. Several embodiments are described herein, and while various features are ascribed to different embodiments, it should be appreciated that the features described with respect to one embodiment may be incorporated with other embodiments as well. By the same token, however, no single feature or features of any described embodiment should be considered essential to every embodiment of the invention, as other embodiments of the invention may omit such features.

Unless otherwise indicated, all numbers used herein to express quantities, dimensions, and so forth used should be understood as being modified in all instances by the term “about.” In this application, the use of the singular includes the plural unless specifically stated otherwise, and use of the terms “and” and “or” means “and/or” unless otherwise indicated. Moreover, the use of the term “including,” as well as other forms, such as “includes” and “included,” should be considered non-exclusive. Also, terms such as “element” or “component” encompass both elements and components comprising one unit and elements and components that comprise more than one unit, unless specifically stated otherwise.

Various embodiments described herein, while embodying (in some cases) software products, computer-performed methods, and/or computer systems, represent tangible, concrete improvements to existing technological areas, including, without limitation, data center technology, sever rack technology, and/or the like. In other aspects, certain embodiments, can improve the functioning of user equipment or systems themselves (e.g., data center devices, server rack devices, etc.). In particular, to the extent any abstract concepts are present in the various embodiments, those concepts can be implemented as described herein by devices, software, systems, and methods that involve specific novel features, such as, providing a modular and portable data center comprising an external case, the external case having a form factor that complies with commercial airline carry-on suitcase dimensions, and the external case comprising: a plurality of slots configured to hold at least two separate datacenter grade server modules within the external case; a fan subassembly contained within the external case; and a power subassembly contained within the external case and configured to provide power to the at least two datacenter grade servers and the fan subassembly, and/or the like, to name a few examples, that extend beyond existing technological areas. These functionalities can produce tangible results outside of existing technological areas, including, merely by way of example, a modular and portable data center that can be carried on to airplanes in carry-on luggage and provide real-time information at the tactical edge and in remote locations, and/or the like, at least some of which may be observed or measured by users of the modular and portable data center.

In an aspect, an apparatus for providing a modular and portable data center might comprise an external case, the external case having a form factor that complies with commercial airline carry-on suitcase dimensions. The external case might include a plurality of slots configured to hold at least two separate datacenter grade server modules within the external case; a fan subassembly contained within the external case; and a power subassembly contained within the external case and configured to provide power to the at least two datacenter grade servers and the fan subassembly.

In some embodiments, the form factor of the external case that complies with commercial airline carry-on suitcase dimensions might be 45 linear inches or less. In some cases, a common sized carry-on bag has dimensions of 9 inches or less by 14 inches or less by 22 inches or less. In this way, the apparatus for providing the modular and portable data center may be taken on most commercial airline flights as a carry-on suitcase.

According to various embodiments, the external case further comprises a handle attached to an outer surface of the external case and at least one wheel attached to the outer surface of the external case. The least one wheel attached to the outer surface of the external case may be removable. By having a handle and at least one wheel, the portable and modular data center may be easily transported anywhere including through an airport. In some embodiments, the external case may be water resistant. In various instances, the external case may be made of at least one of made carbon, metal, plastic, or fabric, and/or the like.

In some embodiments, the external case further comprises the at least two separate datacenter grade server modules held within at least some of the plurality slots. In various instances, a first separate datacenter grade server module of the at least two separate datacenter grade server modules has a first size and is contained within a one or more first slots of the plurality of slots and a second separate datacenter grade server module of the at least two separate datacenter grade server modules has a second height and is contained within one or more second slots of the plurality of slots. In some cases, the first separate datacenter grade server module of the at least two separate datacenter grade server modules has a single slot height and is contained within a first slot of the plurality of slots and the second separate datacenter grade server module of at least two separate datacenter grade server modules has a two-slot height and is contained within two slots of the plurality of slots. In various cases, least two separate datacenter grade server modules each comprise the ability to operate at least 24-core CPUs.

In some embodiments, the external case further includes an internal case contained within the external case. In various instances, the internal case has the plurality of slots defined by one or more mounting brackets. The at least two separate datacenter grade server modules may be held within the plurality of slots via the one or more mounting brackets. In some cases, the mounting brackets may include six axis anti-vibration mounts.

According to some embodiments, the power subassembly may include dual power inputs. Each of the dual power inputs may provide power to the at least two separate datacenter grade server modules and the fan subassembly. In some instances, each of the dual power inputs may be hot swappable. In various cases, each of the dual power inputs may provide redundant power for another of the dual power inputs. If one of the dual power inputs fails, the other of the dual power inputs may continue to provide power to the at least two separate datacenter grade server modules and the fan subassembly.

In some embodiments, the fan subassembly may comprise at least two fans. In some cases, the fan subassembly comprises at least six fans. The fan subassembly may be located at an end of the external cases.

According to some embodiments, the external case further includes a storage module for storing at least one of 512 gigabytes (“GB”) of random-access memory (“RAM”) or 8 terabytes (“TB”) of non-volatile memory (“NVM”) storage, and/or the like. The external case may also include at least one of a full height, full-length (“FHFL”) double-wide graphics processing unit (“GPU”) contained within the external case or a half-height, half-length (“HEEL”) peripheral component interconnect express (“PCIe”) add-in card.

In another aspect, a system might include a first external case, the first external case having a first form factor that complies with commercial airline carry-on suitcase dimensions. The first external case might include at least two separate and first datacenter grade server modules contained within the first external case; a first fan subassembly contained within the first external case; and a first power subassembly contained within the first external case and configured to provide power to the at least two separate and first datacenter grade server modules and the first fan subassembly.

In some embodiments, the system might further include a computer external to the first external case and communicatively coupled to the at least two separate and first datacenter grade server modules contained within the first external case. In some cases, the computer may provide a graphical user interface for a user to interact with the at least two datacenter grade server modules.

According to some embodiments, the system might further include a second external case, the second external case having a second form factor that complies with commercial airline carry-on suitcase dimensions. The second external case might include at least two separate and second datacenter grade server modules contained within the second external case; a second fan subassembly contained within the second external case; and a second power subassembly contained within the second external case and configured to provide power to the at least two separate and second datacenter grade server modules and the second fan subassembly. In various instances, the at least two separate and first datacenter grade server modules may be communicatively coupled to the at least two separate and second datacenter grade server modules and function as a cluster.

Various modifications and additions can be made to the embodiments discussed without departing from the scope of the invention. For example, while the embodiments described above refer to particular features, the scope of this invention also includes embodiments having different combination of features and embodiments that do not include all of the above described features.

### Specific Exemplary Embodiments

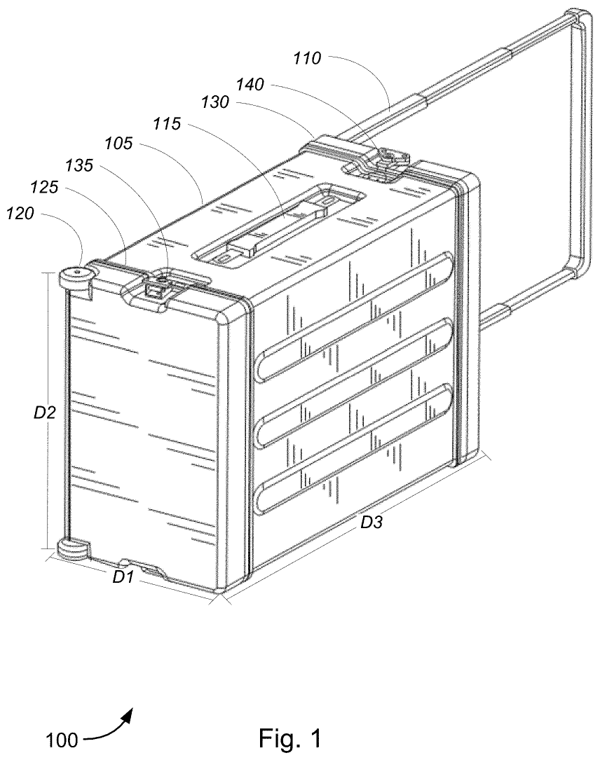

We now turn to the embodiments as illustrated by the drawings. FIGS. 1-12 illustrate some of the features of the method, system, and apparatus for implementing a modular and portable data center, and, in particular embodiments, to methods, systems, and apparatuses for implementing a modular and portable data center that fits within a carry-on suitcase. The methods, systems, and apparatuses illustrated by FIGS. 1-12 refer to examples of different embodiments that include various components and steps, which can be considered alternatives or which can be used in conjunction with one another in the various embodiments. The description of the illustrated methods, systems, and apparatuses shown in FIGS. 1-12 is provided for purposes of illustration and should not be considered to limit the scope of the different embodiments.

With reference to the figures, FIG. 1 is a perspective view of a modular and portable data center 100, in accordance with various embodiments.

In the non-limiting embodiment of FIG. 1, the modular and portable data center 100 might include an external case 105. The external case 105 might be configured to comply with commercial airline carry-on suitcase dimensions. In some cases, commercial airline carry-on suitcase dimensions may be 45 linear inches or less. In a non-limiting example, the external case 105 might have a first dimension D1 of 9 inches or less, a second dimension D2 of 14 inches or less, and/or a third dimension D3 of 22 inches or less. In other words, the external case 105 might have dimensions of 9 inches or less by 14 inches or less by 22 inches or less.

The external case 105 might be made from at least one of carbon, metal, plastic, or fabric, and/or the like. In some cases, the external case 105 may be water resistant and prevent water from entering the interior of the external case 105. An interior of the external case 105 may be lined with at least one of rubber, Gore-Tex, and/or the like.

The external case 105 might include a first handle 110 and a second handle 115. The first handle 110 and/or the second handle 115 might be retractable handles. In some cases, the external case 105 might further include one or more wheels 120. In some cases, there may be at least two wheels 120 as shown in FIG. 1. Alternatively, there may be at least four wheels 120 (not shown). The external case 105 may incorporate handles 110 and 115 and wheels 120 to facilitate easy travel and handling by one person. In some cases, handles 110 and 115 and wheels 120 may be removably attached to external case 105.

The external case 105 might further include a first end piece 125 and/or a second end piece 130. In some cases, the first end piece 125 and/or the second end piece 130 may be removable. The end piece 125 and/or end piece 130 may be fully removable from the external case 105 or partially removable from external case 105. The first removable end piece 125 might be attached to the external case 105 by at least one of a first zipper (not shown), one or more first clips 135, and/or the like. The second removable end piece 130 might be attached to external case 105 by at least one of a second zipper (not shown), one or more second clips 140, and/or the like. In some cases, a gasket (not shown) and/or the like may be placed around the first end piece 125 and/or the second end piece 130 to prevent water from entering the external case 105.

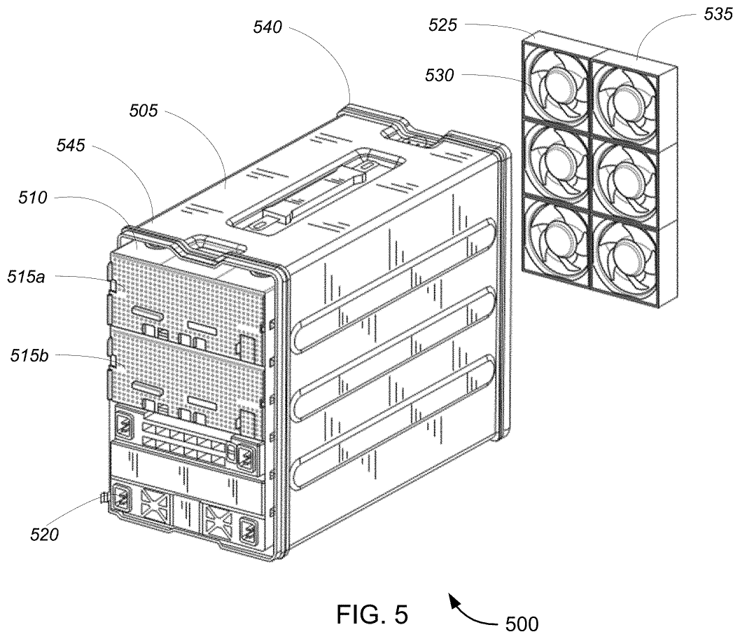

In some instances, the first end piece 125 of the external case and/or the second end piece 130 of the external case 105 might contain one or more apertures (not shown) configured to allow air to flow through the external case 105 from the first end piece 125 to the second end piece 130 and/or to allow air to flow from the second end piece 130 to the first end piece 125. In some cases, a fan subassembly (shown in FIG. 5) may be configured cause air to flow through the external case 105 from the first end piece 125 to the second end piece 130 and/or to allow air to flow from the second end piece 130 to the first end piece 125.

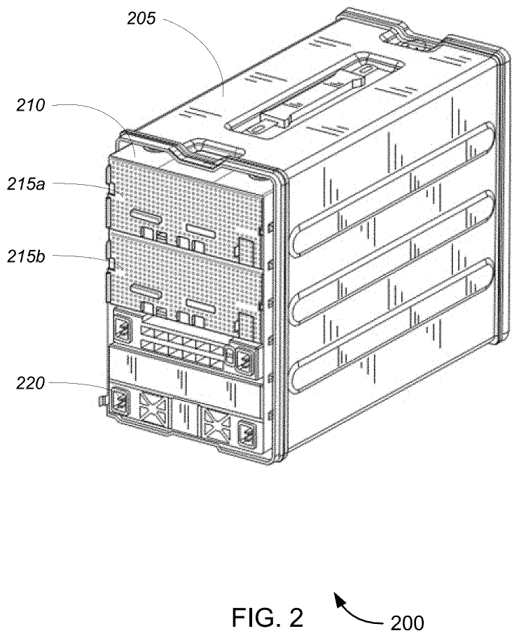

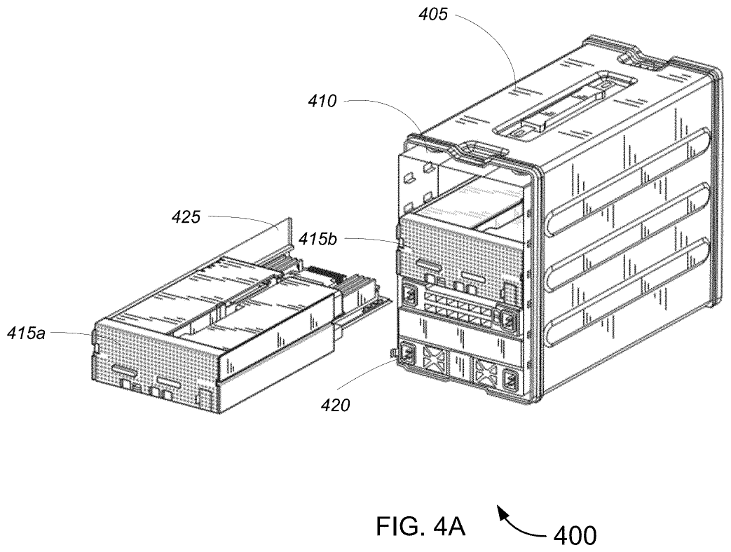

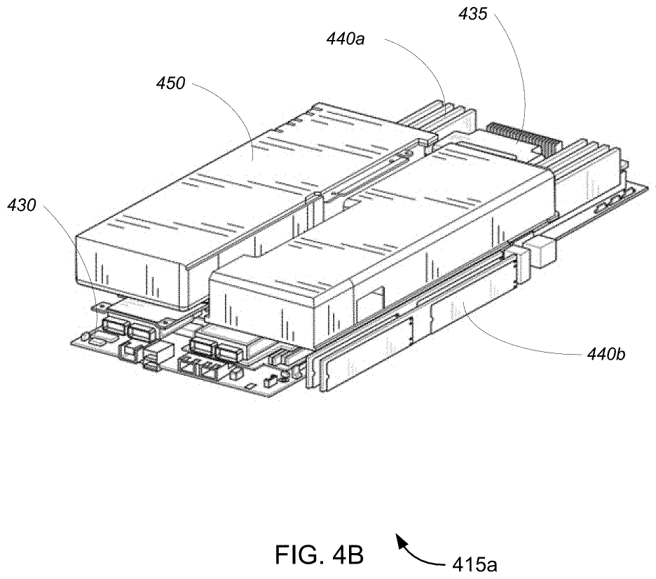

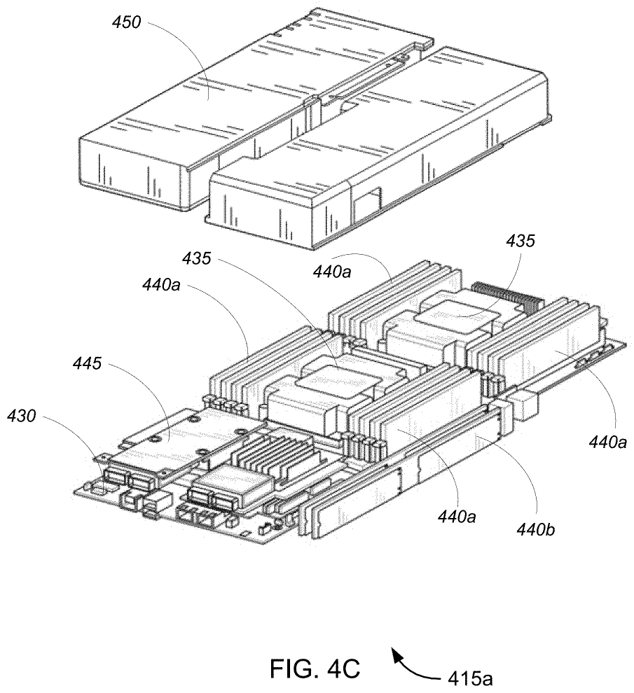

The external case 105 might further include an internal case (shown in FIGS. 2-6), at least two separate datacenter grade server modules (shown in FIGS. 2 and 3-8), a fan subassembly (shown in FIG. 4), a power subassembly (shown in FIGS. 2 and 3-7), and/or the like.

These and other functions of the system for implementing a portable and modular data center 100 (and its components) are described in greater detail below with respect to FIGS. 2-10.

FIG. 2 is a perspective view of a modular and portable data center 200 with a first end of the external case 205 removed, in accordance with various embodiments.

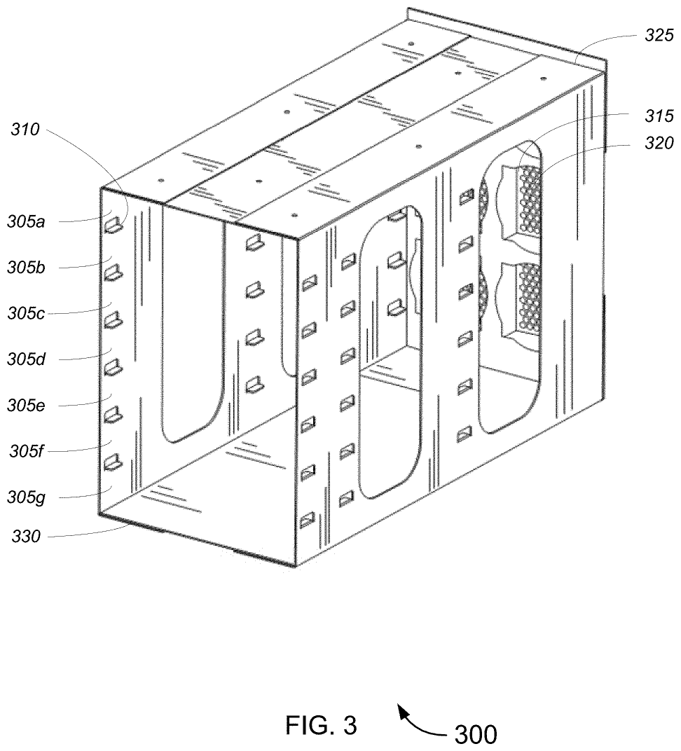

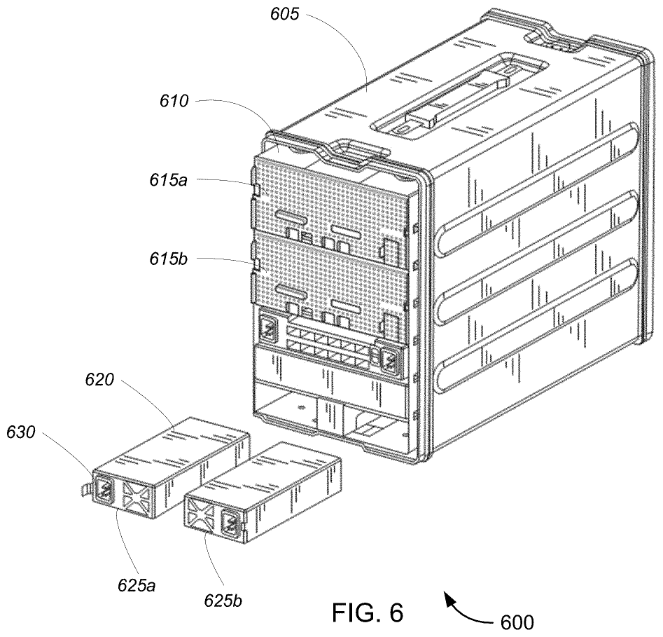

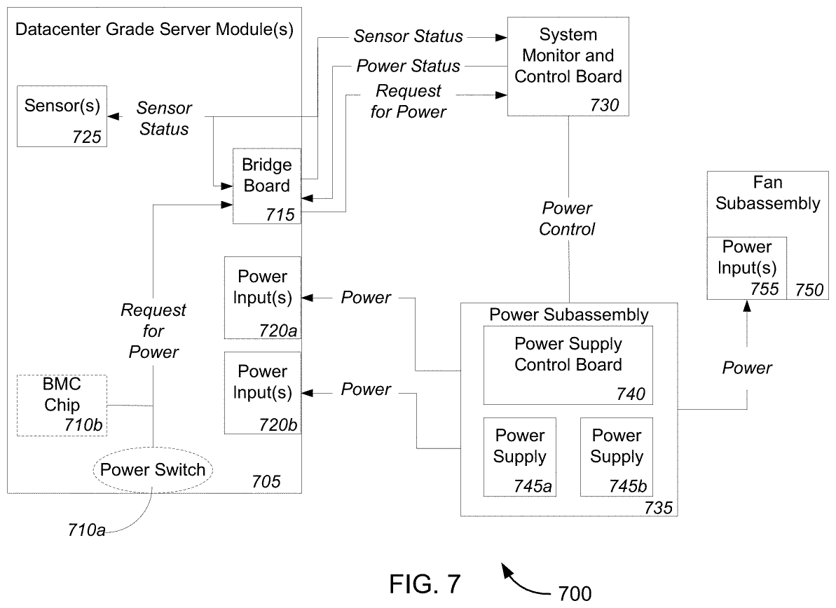

In the non-limiting embodiment of FIG. 2, the modular and portable data center 200 might include an external case 205 (similar to external case 105 of FIG. 1), an internal case 210 (described in more detail in FIG. 3), one or more datacenter grade server modules 215a and 215b (described in more detail in FIG. 4), a power subassembly 220 (described in more detail in FIGS. 6 and 7), and/or the like. FIG. 2 shows only one possible configuration of how components, equipment, and/or canisters can be arranged in the external case 205 of the modular and portable data center 200. A person of ordinary skill in the art would understand that there are many different ways each component, piece of equipment, and/or canister can be arranged within the external case 205 of the modular and portable data center 200.

These and other functions of the system for implementing a portable and modular data center 200 (and its components) are described in greater detail below with respect to FIGS. 3-10.

FIG. 3 is a perspective view of an internal case 300 of a modular and portable data center (which may be similar to the modular and portable data centers 100 and 200 of FIGS. 1 and 2), in accordance with various embodiments.

In the non-limiting embodiment of FIG. 3, the internal case 300 might be contained within an external case (which may be external case 105 or external case 205 shown in FIGS. 1 and 2). The internal case 300 may be removably contained within the external case or permanently contained within the external case. In some embodiments, the internal case 300 may be capable of sliding into and out of the external case. In some cases, the internal case 300 may be made of a durable rigid material, including, but not limited to, metal, plastic, carbon, and/or the like.

In some instances, the internal case 300 might comprise a plurality of slots 305a-305g (collectively, slots 305) defined by one or more mounting brackets 310. Each slot 305 may be configured to hold different types of equipment or canisters (e.g., one or more datacenter grade server modules, one or more storage modules, one or more graphics processing units, one or more add-in cards, one or more power subassemblies, and/or the like) of the modular and portable datacenter. In the non-limiting example of FIG. 3, there are 7 slots 305a-305g shown within internal case 300. However, internal case 200 may have more or less than 7 slots 305a-305g. In some instances, each slot 305 may be at least one rack unit or 1U. In other words, each slot 305 may be at least 1.75 inches in height. In a non-limiting example, the internal case 300 may be configured to contain six 1U canister or equipment slots for one or more datacenter grade server modules and/or components of the one or more datacenter grade server modules and a one 1U power slot for one or more power subassemblies. Slots 305 may also be bigger than or less than 1U.

Each slot 305 may be configured to hold one or more equipment or canisters (e.g., one or more datacenter grade server modules, one or more storage modules, one or more graphics processing units, one or more add-in cards, one or more power subassemblies, and/or the like) via the one or more mounting brackets 310. Each piece of equipment or canister may be configured to be removably contained within slots 305. In a non-limiting example, each piece of equipment or canister may be configured to be able to easily slide into or out of a corresponding slot 305.

In some cases, the one or more mounting brackets 310 might include six axis anti-vibration mounts. In this way, the one or more mounting brackets 310 may be able to protect equipment or canisters contained within the slots 305 from vibration caused by dragging or carrying the external case and/or from vibration caused by travel on one or more airplanes, in one or more cars, by one or more trains, and/or the like.

In some cases, the internal case 300 might further include one or more fan recesses 315. One or more fans and/or fan subassemblies (shown in FIG. 5) may be held within the one or more fan recesses 315. In some instances, there may be six fan recesses 315 configured to contain six fans. However, there may be more than or less than six fan recesses and/or more than or less than six fans. In various instances, the one or more fan recesses 315 may have one or more apertures 320 configured to allow air to flow from a first end 325 of the interior case 300 to a second end 330 of the interior case 300 and configured to cool equipment or canisters (e.g., one or more datacenter grade server modules, one or more storage modules, one or more graphics processing units, one or more add-in cards, one or more power subassemblies, and/or the like) contained within the interior case 300.

These and other functions of internal case 300 are described in greater detail below with respect to FIGS. 4-12.

FIGS. 4A-4C are schematic diagrams illustrating perspective views for a modular and portable data center 400 with one or more datacenter grade server modules 415a and 415b (collectively, datacenter grade server modules 415) removed, in accordance with various embodiments.

In particular, FIGS. 4A-4C focus on the one or more datacenter grade server modules 415a and 415b and the components of the one or more datacenter grade server modules 415a and 415b. FIG. 4A shows a view of an external case 405 with one datacenter grade server module 415a removed. FIG. 4B shows a view of one datacenter grade server module 415a with the chassis 425 removed. FIG. 4C shows a view of one datacenter grade server module 415a with the graphics processing unit (“GPU”) 450 lifted to reveal other datacenter grade server module 415 components. FIG. 4 shows only one possible configuration of how components can be arranged within the one or more datacenter grade server modules 415. A person of ordinary skill in the art would understand that there are many different ways each component can be arranged within the one or more datacenter grade server modules 415.

In the non-limiting embodiment of FIG. 4, the modular and portable data center 400 might include an external case 405 (similar to external case 105 and 205 of FIGS. 1 and 2), an internal case 410 (similar to internal case 210 and 300 of FIGS. 2 and 3), one or more datacenter grade server modules 415a and 415b (similar to one or more datacenter grade server modules 215a and 215b of FIG. 2), a power subassembly 420 (similar to power subassembly 220 FIG. 2), and/or the like.

In some cases, as shown in FIG. 4A, the external case 405 might include at least two datacenter grade server modules 415a and 415b (collectively, datacenter grade server modules 415). Although two datacenter grade server modules 415a and 415b are shown in FIG. 4, there could be any number, combination, and/or sizes of datacenter grade server modules contained within the external case 405. For example, the external case 405 may include at least four 1U datacenter grade server modules, one 2U datacenter grade server module and one 1U datacenter grade server modules, one 2U datacenter grade server module and at least two 1U datacenter grade server modules, two 2U datacenter grade server modules, at least six 1U datacenter grade server modules, at least three 2U datacenter grade server modules, and/or any other number, combination, and/or sizes of datacenter grade server modules capable of fitting within the slots of internal case 410, and/or the like. In some cases, each datacenter grade server module 415 may have a height that is bigger than, smaller than, or equivalent to 1U.

Each datacenter grade server module 415 might sit within a chassis 425 shown in FIG. 4A. The chassis 425 might be configured to allow for easy insertion and/or removal of the one or more datacenter grade server modules 415 within the internal case 410. The chassis 425 may be made from a rigid material such as plastic, metal, carbon, and/or the like and provide protection for the one or more datacenter grade server modules 415 contained with the chassis 425.

In some embodiments, as shown in FIGS. 4B and 4C, each datacenter grade server module 415 might have a motherboard 430 coupled to chassis 425. The motherboard 430 might communicatively couple one or more components of the datacenter grade server module 415 together. For example, the motherboard 430 might communicatively couple together two or more of one or more computer processing units (“CPU”) 435, one or more storage modules 440, one or more add-in cards 445, one or more graphics processing units (“GPUs”) 450, and/or the like.

In some instances, the motherboard 430 might have the ability to operate one or more CPUs 435. In some cases, each datacenter grade server module 415 might include at least two 24-core CPUs 435a and 435b, and/or the like. Each of the CPUs 435 contained within the modular and portable datacenter 400 might be communicatively coupled together. The CPUs 435 might be an Intel Xeon 2nd gen, 6252, and/or the like.

Additionally, each datacenter grade server module 415 might include one or more storage modules 440. In some cases, the storage modules 440 might be random access memory (“RAM”) 440a and non-volatile memory (“NVM”) 440b. In various instances, the RAM 440a provided by each datacenter grade server module 415 might be at least 512 gigabytes (“GB”) and the NVM 440b provided by each datacenter grade server module 415 might be at least 8 terabytes (“TB”).

In some cases, each datacenter grade server module 415 and/or motherboard 430 might include add-in card connectivity. In some cases, the add-in card connectivity of each datacenter grade server module 415 and/or motherboard 430 provides the ability to hold one or more add-in cards 445. In various instances, the add-in cards 445 might be at least two half-height, half-length (“HHHL”) add-in cards 445. For example, the add-in cards 445 might include Peripheral Component Interconnect (“PCI”) add-in cards and/or Peripheral Component Interconnect express (“PCIe”) add-in cards, and/or the like. The PCI and/or PCIe cards might include network interface cards (“NICs”), graphics cards, solid state drives, or other industry standard PCI cards, and/or the like.

In some embodiments, each datacenter grade server module 415 might further include at least one GPU 450. In some cases, the at least one GPU 450 might be a full height, full-length (“FHFL”) GPU. The GPU 450 might be, without limitation, an Nvidia V100, and/or the like.

In some cases, each datacenter grade server module 415, motherboard 430, CPUs 435, memory modules 440, add-in cards 445, and/or GPUs 450 might each include one or more temperature sensors (not shown). When a datacenter grade server module 415, CPUs 435, and/or the like detect that one or more components (e.g., motherboard 430, CPUs 435, memory modules 440, add-in cards 445, and/or GPUs 450) of the datacenter grade server module 415 are overheating, the datacenter grade server module 415, CPUs 435, and/or the like may send a signal to the power subassembly 420 and/or a fan subassembly to turn the fan subassembly on and/or to increase power to the fan subassembly to cause the one or more fans to spin faster. This causes the one or more fans to blow air and cool the one or more components within the external case 405 and within the one or more datacenter grade server modules 415.

Each datacenter grade server module 415 located within external case 405 may be communicatively coupled together to function as a cluster. In a non-limiting example, datacenter grade server module 415a may be communicatively coupled to datacenter grade server module 415b. In some cases, at least one datacenter grade server module 415 includes a high-speed networking card with a minimum of 40 gigabit ethernet (“GbE”) to facilitate cluster connectivity between the datacenter grade server module 415a and the datacenter grade server module 415b. In various instances, at least one datacenter grade server module 415 includes a high-speed networking switch with a minimum of 40 GbE to connect the datacenter grade server module 415a to datacenter grade server module 415b via one or more networking cables.

These and other functions of the modular and portable data center 400 and the one or more datacenter grade server modules 415 are described in greater detail below with respect to FIGS. 5-10.

FIG. 5 is a perspective view of a modular and portable data center 500 with a fan subassembly 525, in accordance with various embodiments.

In the non-limiting embodiment of FIG. 5, the modular and portable data center 500 might include an external case 505 (similar to external case 105, 205, and 405 of FIGS. 1, 2, and 4), an internal case 510 (similar to internal case 210, 300, and 410 of FIGS. 2, 3, and 4), one or more datacenter grade servers 515a and 515b (similar to the one or more datacenter grade servers 215a, 215b, 415a, and 415b of FIGS. 1 and 4), a power subassembly 520 (similar to power subassemblies 220 and 420 of FIGS. 1 and 4), and a fan subassembly 525, and/or the like.

In some embodiments, the fan subassembly 525 may fit within and be contained within the external case 505. Alternatively, in some cases, the fan subassembly 525 may be transported separately from the external case 505 and assembled to the external case 505 in the field.

In various cases, the fan subassembly 525 may include one or more fans 530. Although six individual fans 530 are shown in FIG. 5, there may be more or less fans 530. The one or more fans 530 may be contained within chassis 535. The chassis 535 may be made from a rigid material such as plastic, metal, carbon, and/or the like and provide protection for the one or more fans 530 contained with the chassis 535. In some cases, the chassis 535 may be configured to be removably coupled to the internal case and/or the one or more fan recesses (shown in FIG. 3) of the internal case.

In some instances, the one or more fans 530 may be configured to blow air through the external case 505 from a first end 540 of the external case 505 to a second end 545 of the external case 505. The one or more fans 530 may be configured to cool the one or more components contained within external case 505 such as the one or more datacenter grade servers 515 and/or the power subassembly 520. The one or more fans 530 may be configured to enable the one or more components in the external case 505 to operate in temperatures of 30 degrees Celsius or higher.

These and other functions of the modular and portable data center 500 and the fan subassembly 525 are described in greater detail below with respect to FIGS. 6-10.

FIG. 6 is a perspective view of a modular and portable data center 600 with the power subassembly 620 removed, in accordance with various embodiments.

In the non-limiting embodiment of FIG. 6, the modular and portable data center 600 might include an external case 605 (similar to external case 105, 205, 405, and 505 of FIGS. 1, 2, 4, and 5), an internal case 610 (similar to internal case 210, 300, 410, and 510 of FIGS. 2, 3, 4, and 5), one or more datacenter grade servers 615a and 615b (similar to the one or more datacenter grade servers 215a, 215b, 415a, 415b, 515a, and 515b of FIGS. 1, 4, and 5), a power subassembly 620 (similar to power subassemblies 220, 420, and 520 of FIGS. 1, 4, and 5), and/or the like.

In some embodiments, the power subassembly 620 may take up 1U of the internal case 610. Additionally and/or alternatively, the power subassembly 620 may take up more than or less than 1U of the internal case 610. The power subassembly 620 might include dual redundant power inputs or supplies 625a and 625b (collectively, power inputs 625). Each of the dual redundant power inputs 625 might have a power outlet 630 configured to receive power from at least one of a wall outlet, a generator, a battery, and/or the like.

Each of the dual power inputs 625a and 625b may provide power to equipment or canisters contained within external case 605. For example, each of the dual power inputs 625a and 625b may provide power to the one or more datacenter grade server modules 615a and 615b and/or components of the one or more datacenter grade server modules 615a and 615b, the fan subassembly (not shown in FIG. 6), and/or the like. In some cases, the dual power inputs 625a and 625b may provide power to equipment or canisters contained within external case 605 via one or more busbars. In various cases, the power subassembly 620 may provide a minimum of 2 kilowatts of energy at 209 volts per power input. When there are two power inputs 625a and 625b, the power subassembly 620 may provide at least 4 kilowatts of energy.

In some embodiments, the dual power inputs 625a and 625b may be hot swappable to allow replacement of at least one power input 625 without interrupting the supply of power to equipment or canisters (e.g., the one or more datacenter grade server modules 615a and 615b, the fan subassembly, and/or the like) contained within external case 605. In some cases, each of the dual power inputs 625a and 625b may provide redundant power for another of the dual power inputs 625a and 625b. In a non-limiting example, if one of the dual power inputs 625a and/or 625b fails, the other of the dual power inputs 625a and/or 625b continues to provide power to the equipment or canisters (e.g., the one or more datacenter grade server modules 615a and 615b, the fan subassembly, and/or the like) contained within external case 605.

These and other functions of the portable and modular data center 600 and the power subassembly 620 are described in greater detail below with respect to FIGS. 7-10.

FIG. 7 is a schematic diagram illustrating a system 700 for controlling and distributing power in a modular and portable data center, in accordance with various embodiments.

In the non-limiting example of FIG. 7, system 700 might include one or more datacenter grade server modules 705 (which may be similar to the one or more datacenter grade server modules 215a, 215b, 415a, 415b, 515a, 515b, 615a, and 615b of FIGS. 1, 4, 5, and 6). The at least one datacenter grade server module 705 might include one or more power controllers 710, one or more bridge boards or processors 715, one or more power inputs 720a and 720b (collectively, power inputs 720), one or more sensor(s) 725, and/or the like. In various instance, the one or more power controllers 710 may be at least one or a power switch 710a and/or a baseboard management controller (BMC Chip) 710b. In some cases, the one or more sensors 725 might be one or more temperature sensors, humidity sensors, moisture sensors, and/or the like. The one or more datacenter grade server modules 705 might further include one or more motherboards (not shown), one or more CPUs (not shown), one or more storage modules (not shown), one or more add-in cards (not shown), one or more GPUs (not shown), and/or the like.

System 700 might further include a system monitor and control board or processing unit 730 and a power subassembly 735. In some cases, the power subassembly might include a power supply control board (“PSCB”) or processor 740 and one or more power supplies 745a and 745b. In some instances, the one or more power supplies 745 might be one or more power inputs and receive power from an outside source such as a wall outlet, a generator, or a battery, and/or the like. In various embodiments, the power controller 710 may be located on the power subassembly 735 instead of the datacenter grade server module 705. In some instances, system 700 might further include a fan subassembly 750 with one or more power input(s) 755 and one or more fans (not shown).

The power subassembly 735 might include dual redundant power inputs or supplies 745a and 745b. Each of the dual power inputs 745a and 745b may provide power to equipment or canisters contained within an external case of the modular and portable data center. For example, each of the dual power inputs 745a and 745b may provide power to the one or more datacenter grade server modules 705, components of the one or more datacenter grade server modules 705, the fan subassembly 750, and/or the like. In various cases, the power subassembly 735 may provide a minimum of 2 kilowatts of energy at 209 volts per power input 745. When there are two power inputs 745a and 745b, the power subassembly 740 may provide at least 4 kilowatts of energy.

In some embodiments, the dual power inputs 745a and 745b may be hot swappable to allow replacement of at least one power input 745 without interrupting the supply of power to equipment or canisters contained within the modular and portable data center. In some cases, each of the dual power inputs 745a and 745b may provide redundant power for another of the dual power inputs 745a and 745b. In a non-limiting example, if one of the dual power inputs 745a and/or 745b fails, the other of the dual power inputs 745a and/or 745b continues to provide power to the equipment or canisters contained within the modular and portable data center.

In some cases, the system monitor and control board 730 might be integrated into the bridge board 715 of the datacenter grade server module 705, the one or more CPUs of the datacenter grade server module 705, and/or the PSCB 740 of the power subassembly 735. Alternatively, the system monitor and control board 730 might be a separate central processing unit integrated into the datacenter grade server module 705, power subassembly, fan subassembly 750, and/or the like. Alternatively, the system monitor and control board 730 might be a central processing unit separate from the datacenter grade server module 705, power subassembly 735, and/or fan subassembly 750. The system monitor and control board 730 might be configured to monitor the environment of the external case via the power controller 710, via the one or more sensors 725, and/or the like and the system monitor and control board 730 might be configured to control one or more operations in response to the monitored environment of the external case.

In operation, when the power controller 710 is a power switch 710a and when a user interacts with the power switch 710a on the one or more datacenter grade server modules 705 and/or the power subassembly 735, the power switch 710a may provide a power request to the one or more datacenter grade server modules 705, the system monitor control board 730, and/or the power subassembly 735. Upon receipt of the power request, the one or more datacenter grade server modules 705, the system monitor control board 730, and/or the power subassembly 735 will send a power request to the PSCB 740. When the one or more datacenter grade server modules 705 issue the request for power, the request may be sent via bridge board 715 and system monitor and control board 730 to PSCB 740. Alternatively, when the one or more datacenter grade server modules 705 issue the request for power, the request may be sent via bridge board 715 to PSCB 740. When the power subassembly 735 issues the request for power, the request may be sent directly to the PSCB 740. When the PSCB 740 receives the request for power, the PSCB 740 may turn on the main power and check for power status. The PSCB 740 may then provide power to the datacenter grade server modules 705 via power inputs 720a and 720b and/or provide power to fan subassembly 750 via power input 755. The PSCB 740 may also report the power status to the one or more datacenter grade server modules 705 via bridge board 715 and/or via system monitor control board 730 and bridge board 715.

Alternatively, instead of having a physical power switch 710a, the datacenter grade server module 705 may be turned on remotely via Baseboard Management Control (“BMC”) chip 710b. The BMC chip 710b may be contacted via one or more wireless signals sent from a remote device via a wireless connection to the BMC chip 710b and/or via one or more signals sent from a remote device via an ethernet connection (e.g., an Ethernet Management Port). After receiving the one or more signals from the remote device, the BMC chip 710b forwards the power request to the PSCB 740. When the one or more datacenter grade server modules 705 issue the request for power, the request may be sent via bridge board 715 and system monitor and control board 730 to PSCB 740. Alternatively, when the one or more datacenter grade server modules 705 issue the request for power, the request may be sent via bridge board 715 to PSCB 740. When the power subassembly 735 issues the request for power, the request may be sent directly to the PSCB 740. When the PSCB 740 receives the request for power, the PSCB 740 may turn on the main power and check for power status. The PSCB 740 may then provide power to the datacenter grade server modules 705 via power inputs 720a and 720b and/or provide power to fan subassembly 750 via power input 755. The PSCB 740 may also report the power status to the one or more datacenter grade server modules 705 via bridge board 715 and/or via system monitor control board 730 and bridge board 715. In some cases, the PSCB 740 may also report the power status to the remote device.

In some instances, the one or more sensors 725 might be communicatively coupled to the system monitor and control board 730. The one or more sensors 725 might be communicatively coupled directly to the system monitor and control board 730. Alternatively, the one or more sensors 725 might be communicatively coupled to the system monitor and control board 730 via bridge board 715. Each component (e.g., one or more motherboards, one or more CPUs, one or more storage modules, one or more add-in cards, one or more GPUs, and/or the like) of the one or more datacenter grade server modules 705 might contain at least one sensor of the one or more sensors 725.

In operation, when the one or more sensors 725, system monitor and control board 730 via the one or more sensors 725, and/or bridge board 715 via the one or more sensors 725 detect that one or more components of the datacenter grade server modules 705 are getting hot or cold, the humidity within the external case is increasing or decreasing, and/or moisture within the external case, the one or more sensors 725, system monitor and control board 730, and/or bridge board 715 might send a power request to the PSCB 740 for power to power the fan subassembly 750. The power request may be a request to turn power on or off to the fan subassembly 750. Alternatively, the power request may be a request to increase or decrease power to the fan subassembly 750. When the PSCB 740 receives the request for power, the PSCB 740 may turn on the main power and check for power status. The PSCB 740 may then provide power to, turn power off, increase power to, and/or decrease power to fan subassembly 750 via power input 755. The PSCB 740 may also report the power status of the fan subassembly to the one or more datacenter grade server modules 705 and/or to a remote device.

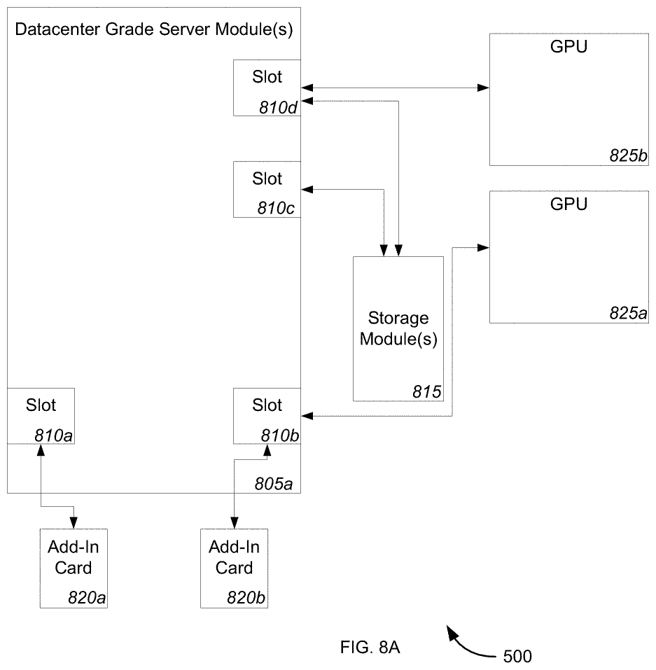

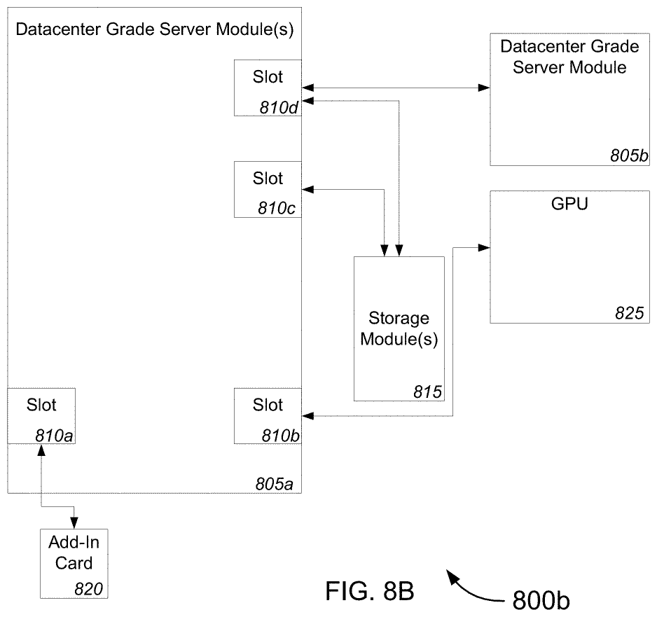

These and other functions of the system 700 are described in greater detail below with respect to FIGS. 8-10.

FIGS. 8A and 8B are schematic diagrams of a system 800 for controlling and distributing one or more signals between one or more components in a modular and portable data center, in accordance with various embodiments. The examples shown in FIGS. 8A and 8B are only two non-limiting ways that one or more components in a modular and portable data center may be communicatively coupled together and a person of ordinary skill in the art would understand that there are many other ways to communicatively couple one or more components in the modular and portable data center.

In the non-limiting examples of FIG. 8, system 800 might include one or more datacenter grade server modules 805a and 805b. The one or more datacenter grade server modules 805 might include one or more slots 810a-810d, one or more storage modules 815, one or more add-in cards 820, one or more GPUs 825, and/or the like. The one or more slots might be one or more peripheral component interconnect express (“PCIe”) slots.

Turning to FIG. 8A, the one or more datacenter grade server modules might have one or more add-in cards 820a communicatively coupled to slot 810a. The slot 810a might be a PCIe with 16 lanes (“x16”). Slot 810b might be used to communicatively couple add-in card 820b to the one or more datacenter grade server modules 805 and GPU 825a to the one or more datacenter grade server modules 805. The slot 810b might be a PCIe x24 (with x16 communicatively coupled to add-in card 820b and x8 communicatively coupled to GPU 825a). Slot 810c might be used to communicatively couple the one or more storage modules 815 to the one or more datacenter grade server modules 805. The slot 810c might be a PCIe x16. Slot 810d might be used to communicatively couple one or more storage modules 815 to the one or more datacenter grade server modules 805 and GPU 825b to the one or more datacenter grade server modules 805. The slot 810d might be a PCIe x24 (with x16 communicatively coupled to the one or more storage modules 815 and x8 communicatively coupled to GPU 825b).

Turning to FIG. 8B, the one or more datacenter grade server modules might have one or more add-in cards 820 communicatively coupled to slot 810a. The slot 810a might be a PCIe x16. Slot 810b might be used to communicatively couple GPU 825 to the one or more datacenter grade server modules 805. The slot 810b might be a PCIe x16 communicatively coupled to GPU 825. Slot 810c might be used to communicatively couple the one or more storage modules 815 to the datacenter grade server modules 805a. The slot 810c might be a PCIe x16. Slot 810d might be used to communicatively couple one or more storage modules 815 to the one or more datacenter grade server modules 805 and communicatively couple the datacenter grade server modules 805b to the datacenter grade server modules 805a. The slot 810d might be a PCIe x24 (with x16 communicatively coupled to the one or more storage modules 815 and x8 communicatively coupled to the datacenter grade server modules 805b).

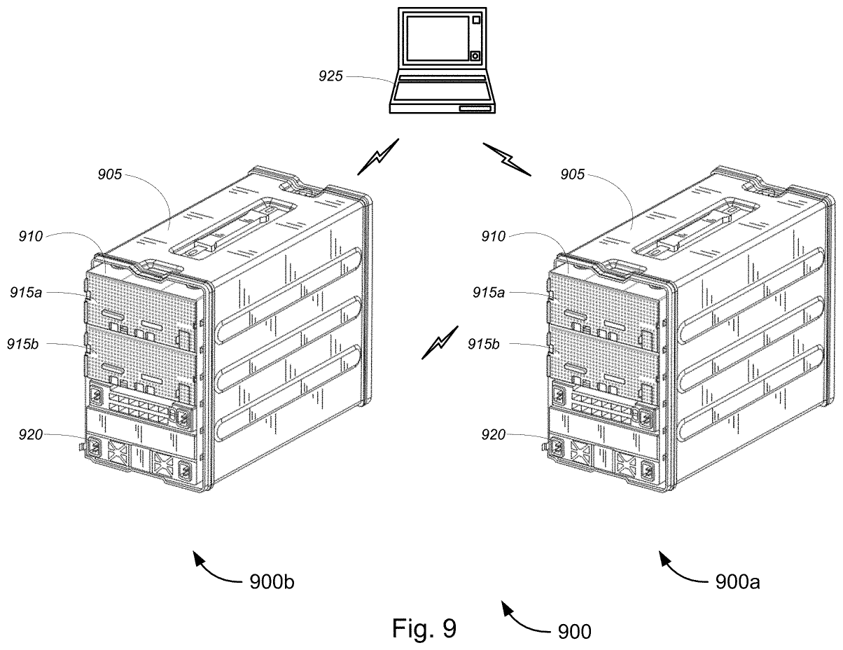

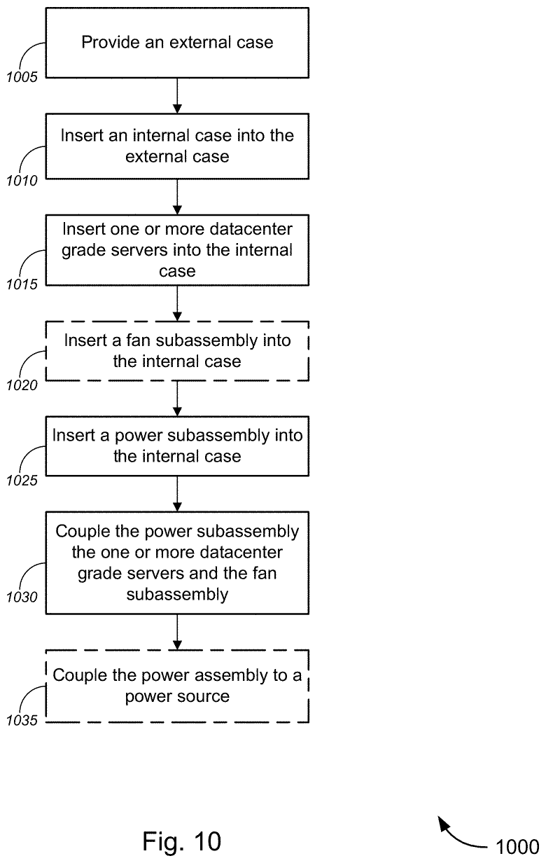

These and other functions of the system 800 are described in greater detail below with respect to FIGS. 9 and 10.

FIG. 9 is a schematic diagram illustrating a system 900 for implementing a cluster of modular and portable data centers 900a and 900b, in accordance with various embodiments.

In the non-limiting embodiment of FIG. 9, there might be at least two modular and portable data centers 900a and 900b. Each portable and modular data center 900a and 900b might include an external case 905 (similar to external case 105, 205, 405, 505, and 605 of FIGS. 1, 2, 4, 5, and 6), an internal case 510 (similar to internal case 210, 300, 410, 510, and 610 of FIGS. 2, 3, 4, 5, and 6), one or more datacenter grade servers 515a and 515b (similar to the one or more datacenter grade servers 215a, 215b, 415a, 415b, 515a, 515b, 615a, and 615b of FIGS. 1, 4, 5, and 6), a power subassembly 920 (similar to power subassemblies 220, 420, 520, and 620 of FIGS. 1, 4, 5, and 6), and/or the like. System 600 might further include a remote device 925. The remote device 925 might be, without limitation, at least one of a computer, a tablet, a laptop, a cellular phone, a smart phone, a gaming console, and/or the like.

The at least two modular and portable data centers 900a and 900b and remote device 925 might be communicatively coupled together via one or more wired and/or wireless connections denoted by the lightning bolt symbols. In some cases, the remote device 925 might be configured to control the at least two modular and portable data centers 900a and 900b. In some cases, the remote device 925 may provide a graphical user interface for a user to interact with the at least two modular and portable datacenters 900a and 900b. For example, the remote device, via user interaction, may be able to turn on or off the at least two modular and portable datacenters 900a and 900b, send data to or receive data from the at least two modular and portable datacenters 900a and 900b, cause the at least two modular and portable datacenters 900a and 900b to perform one or more functions (e.g., process the data, analyze the data, retrieve data from one or more sensors (e.g., one or more temperature sensors, humidity sensors, moisture sensors, location sensors, and/or the like), send data to the one or more sensors, and/or the like), and/or the like.

In some cases, each portable data center 900a and 900b may have one or more connections to allow case to case connectivity. In some cases, the at least two separate and first datacenter grade server modules 915a and 915b of the first modular and portable datacenter 900a may be communicatively coupled to the at least two separate and second datacenter grade server modules 915a and 915b of the second modular and portable datacenter 900b. The at least four datacenter grade server modules 915 may then function together as a cluster.

These and other functions of the system 900 for implementing a portable and modular data center (and its components) are described in greater detail below with respect to FIG. 10

FIG. 10 is a flow diagram illustrating a method 1000 for making a modular and portable data center, in accordance with various embodiments.

While the techniques and procedures are depicted and/or described in a certain order for purposes of illustration, it should be appreciated that certain procedures may be reordered and/or omitted within the scope of various embodiments. Moreover, while the method 1000 illustrated by FIG. 10 can be implemented by or with (and, in some cases, are described below with respect to) the systems, examples, or embodiments 100, 200, 300, 400, 500, 600, 700, 800, and 900 of FIGS. 1, 2, 3, 4, 5, 6, 7, 8, 9, respectively (or components thereof), such methods may also be implemented using any suitable hardware (or software) implementation. Similarly, while each of the systems, examples, or embodiments 100, 200, 300, 400, 500, 600, 700, 800, and 900 of FIGS. 1, 2, 3, 4, 5, 6, 7, 8, 9, respectively (or components thereof), can be made according to the method 500 illustrated by FIG. 5, the systems, examples, or embodiments 100, 200, 300, 400, 500, 600, 700, 800, and 900 of FIGS. 1, 2, 3, 4, 5, 6, 7, 8, 9 can each also be made according to other methods of making.

In the non-limiting embodiment of FIG. 10, method 1000, at block 1005, might comprise providing an external case. The external case might be configured to comply with commercial airline carry-on suitcase dimensions. In some cases, commercial airline carry-on suitcase dimensions may be of 45 linear inches or less. In a non-limiting example, the external case might have a first dimension D1 of 9 inches or less, a second dimension D2 of 14 inches or less, and/or a third dimension D3 of 22 inches or less. In other words, the external case might have dimensions of 9 inches or less by 14 inches or less by 22 inches or less.

The external case might be made from at least one of carbon, metal, plastic, or fabric, and/or the like. In some cases, the external case may be water resistant and prevent water from entering the interior of the external case. An interior of the external case may be lined with at least one of rubber, Gore-Tex, and/or the like.

The external case might include one or more first handles. The one or more first handles might be retractable handles. In some cases, the external case might further include one or more wheels. In some cases, the one or more handles and wheels may be removably attached to the external case.

At block 1010, method 1000 might comprise inserting an internal case into the external case. The internal case may be removably contained within the external case or permanently contained within the external case. In some instances, the internal case might comprise a plurality of slots defined by one or more mounting brackets. Each slot may be configured to hold different types of equipment or canisters (e.g., one or more datacenter grade server modules, one or more storage modules, one or more graphics processing units, one or more add-in cards, one or more power subassemblies, and/or the like).

Next, at block 1015, the method 1000 might include inserting one or more datacenter grade server modules into the internal case. The one or more datacenter grade server modules may be removably inserted into the internal case. In some cases, there could be between one and six (or more) datacenter grade server modules contained within the internal case. Each datacenter grade server module might include, without limitation, a least one of one or more motherboards, one or more computer processing units (“CPUs”), one or more storage modules, one or more add-in cards, one or more graphics processing units (“GPUs”), and/or the like.

At optional block 1020, the method 1000 might continue by inserting a fan subassembly into the internal case. The fan subassembly may include one or more fans. The one or more fans may be configured to blow air inside the external case and cool equipment one or more components contained within external case.

In some embodiments, method 1000, at block 1025 might include inserting a power subassembly into the internal case. At block 1030 the power subassembly might be electrically coupled to the one or more datacenter grade servers and/or the fan subassembly. The power subassembly might include dual redundant power inputs or supplies. Each of the dual redundant power inputs might be configured to receive power from at least one of a wall outlet, a generator, a battery, and/or the like.

Each of the dual power inputs may provide power to equipment or canisters contained within the external case. For example, each of the dual power inputs may provide power to the one or more datacenter grade server modules, the fan subassembly, and/or the like. In some embodiments, the dual power inputs may be hot swappable to allow replacement of at least one power input without interrupting the supply of power to equipment or canisters (e.g., the one or more datacenter grade server modules, the fan subassembly, and/or the like) contained within the external case. In some cases, each of the dual power inputs may provide redundant power for another of the dual power inputs. In a non-limiting example, if one of the dual power inputs fails, the other of the dual power inputs continues to provide power to the equipment or canisters (e.g., the one or more datacenter grade server modules, the fan subassembly, and/or the like) contained within the external case.

In some instances, method 1000, at optional block 1035 might include coupling the power assembly to a power source. The power source might include, without limitation, at least one of a wall outlet, a generator, a battery, and/or the like. Once coupled to the power source, a user may turn on the one or more datacenter grade server modules, the power subassembly, the fan subassembly, and/or the like.

Exemplary System and Hardware Implementation

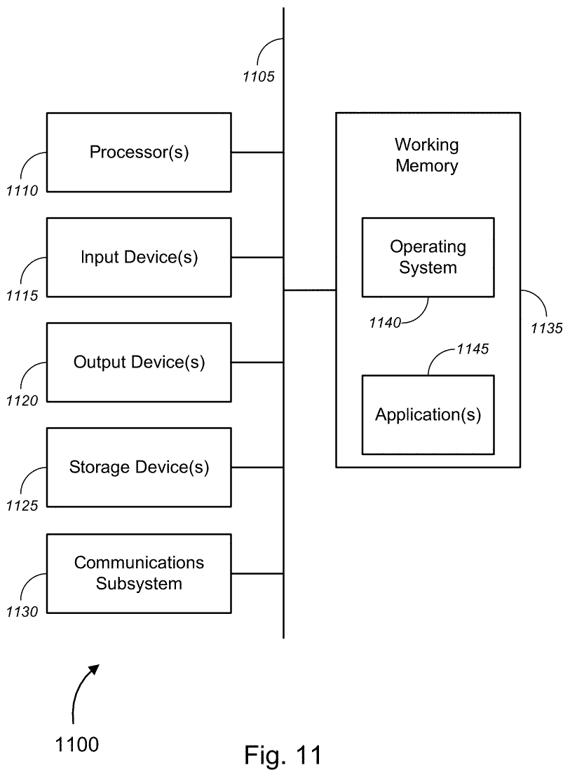

FIG. 11 is a block diagram illustrating an exemplary computer or system hardware architecture, in accordance with various embodiments. FIG. 11 provides a schematic illustration of one embodiment of a computer system 1100 of the hardware that can perform the methods provided by various other embodiments, as described herein, and/or can perform the functions of computer or hardware systems (i.e., modular and portable data center(s) 100, 200, 400, 500, 600, 700, 800, 900, components of the modular and portable data centers 100, 200, 400, 500, 600, 700, 800, 900, and/or remote device 925, etc.), as described above. It should be noted that FIG. 11 is meant only to provide a generalized illustration of various components, of which one or more (or none) of each may be utilized as appropriate. FIG. 11, therefore, broadly illustrates how individual system elements may be implemented in a relatively separated or relatively more integrated manner.

The computer or hardware system 1100—which might represent an embodiment of the computer or hardware system (i.e., modular and portable data center(s) 100, 200, 400, 500, 600, 700, 800, 900, components of the modular and portable data centers 100, 200, 400, 500, 600, 700, 800, 900, and/or remote device 925, etc.), described above with respect to FIGS. 1-10—is shown comprising hardware elements that can be electrically coupled via a bus 1105 (or may otherwise be in communication, as appropriate). The hardware elements may include one or more processors 1110, including, without limitation, one or more general-purpose processors and/or one or more special-purpose processors (such as microprocessors, digital signal processing chips, graphics acceleration processors, and/or the like); one or more input devices 1115, which can include, without limitation, a mouse, a keyboard, and/or the like; and one or more output devices 1120, which can include, without limitation, a display device, a printer, and/or the like.

The computer or hardware system 1100 may further include (and/or be in communication with) one or more storage devices 1125, which can comprise, without limitation, local and/or network accessible storage, and/or can include, without limitation, a disk drive, a drive array, an optical storage device, solid-state storage device such as a random access memory (“RAM”) and/or a read-only memory (“ROM”), which can be programmable, flash-updateable, and/or the like. Such storage devices may be configured to implement any appropriate data stores, including, without limitation, various file systems, database structures, and/or the like.

The computer or hardware system 1100 might also include a communications subsystem 1130, which can include, without limitation, a modem, a network card (wireless or wired), an infra-red communication device, a wireless communication device and/or chipset (such as a Bluetooth™ device, an 802.11 device, a WiFi device, a WiMax device, a WWAN device, cellular communication facilities, etc.), and/or the like. The communications subsystem 1130 may permit data to be exchanged with a network (such as the network described below, to name one example), with other computer or hardware systems, and/or with any other devices described herein. In many embodiments, the computer or hardware system 1100 will further comprise a working memory 1135, which can include a RAM or ROM device, as described above.

The computer or hardware system 1100 also may comprise software elements, shown as being currently located within the working memory 1135, including an operating system 1140, device drivers, executable libraries, and/or other code, such as one or more application programs 1145, which may comprise computer programs provided by various embodiments (including, without limitation, hypervisors, VMs, and the like), and/or may be designed to implement methods, and/or configure systems, provided by other embodiments, as described herein. Merely by way of example, one or more procedures described with respect to the method(s) discussed above might be implemented as code and/or instructions executable by a computer (and/or a processor within a computer); in an aspect, then, such code and/or instructions can be used to configure and/or adapt a general purpose computer (or other device) to perform one or more operations in accordance with the described methods.

A set of these instructions and/or code might be encoded and/or stored on a non-transitory computer readable storage medium, such as the storage device(s) 1125 described above. In some cases, the storage medium might be incorporated within a computer system, such as the system 1100. In other embodiments, the storage medium might be separate from a computer system (i.e., a removable medium, such as a compact disc, etc.), and/or provided in an installation package, such that the storage medium can be used to program, configure, and/or adapt a general purpose computer with the instructions/code stored thereon. These instructions might take the form of executable code, which is executable by the computer or hardware system 1100 and/or might take the form of source and/or installable code, which, upon compilation and/or installation on the computer or hardware system 1100 (e.g., using any of a variety of generally available compilers, installation programs, compression/decompression utilities, etc.) then takes the form of executable code.

It will be apparent to those skilled in the art that substantial variations may be made in accordance with specific requirements. For example, customized hardware (such as programmable logic controllers, field-programmable gate arrays, application-specific integrated circuits, and/or the like) might also be used, and/or particular elements might be implemented in hardware, software (including portable software, such as applets, etc.), or both. Further, connection to other computing devices such as network input/output devices may be employed.

As mentioned above, in one aspect, some embodiments may employ a computer or hardware system (such as the computer or hardware system 1100) to perform methods in accordance with various embodiments of the invention. According to a set of embodiments, some or all of the procedures of such methods are performed by the computer or hardware system 1100 in response to processor 1110 executing one or more sequences of one or more instructions (which might be incorporated into the operating system 1140 and/or other code, such as an application program 1145) contained in the working memory 1135. Such instructions may be read into the working memory 1135 from another computer readable medium, such as one or more of the storage device(s) 1125. Merely by way of example, execution of the sequences of instructions contained in the working memory 1135 might cause the processor(s) 1110 to perform one or more procedures of the methods described herein.

The terms “machine readable medium” and “computer readable medium,” as used herein, refer to any medium that participates in providing data that causes a machine to operate in a specific fashion. In an embodiment implemented using the computer or hardware system 1100, various computer readable media might be involved in providing instructions/code to processor(s) 1110 for execution and/or might be used to store and/or carry such instructions/code (e.g., as signals). In many implementations, a computer readable medium is a non-transitory, physical, and/or tangible storage medium. In some embodiments, a computer readable medium may take many forms, including, but not limited to, non-volatile media, volatile media, or the like. Non-volatile media includes, for example, optical and/or magnetic disks, such as the storage device(s) 1125. Volatile media includes, without limitation, dynamic memory, such as the working memory 1135. In some alternative embodiments, a computer readable medium may take the form of transmission media, which includes, without limitation, coaxial cables, copper wire, and fiber optics, including the wires that comprise the bus 1105, as well as the various components of the communication subsystem 1130 (and/or the media by which the communications subsystem 1130 provides communication with other devices). In an alternative set of embodiments, transmission media can also take the form of waves (including without limitation radio, acoustic, and/or light waves, such as those generated during radio-wave and infra-red data communications).

Common forms of physical and/or tangible computer readable media include, for example, a floppy disk, a flexible disk, a hard disk, magnetic tape, or any other magnetic medium, a CD-ROM, any other optical medium, punch cards, paper tape, any other physical medium with patterns of holes, a RAM, a PROM, and EPROM, a FLASH-EPROM, any other memory chip or cartridge, a carrier wave as described hereinafter, or any other medium from which a computer can read instructions and/or code.

Various forms of computer readable media may be involved in carrying one or more sequences of one or more instructions to the processor(s) 1110 for execution. Merely by way of example, the instructions may initially be carried on a magnetic disk and/or optical disc of a remote computer. A remote computer might load the instructions into its dynamic memory and send the instructions as signals over a transmission medium to be received and/or executed by the computer or hardware system 1100. These signals, which might be in the form of electromagnetic signals, acoustic signals, optical signals, and/or the like, are all examples of carrier waves on which instructions can be encoded, in accordance with various embodiments of the invention.

The communications subsystem 1130 (and/or components thereof) generally will receive the signals, and the bus 1105 then might carry the signals (and/or the data, instructions, etc. carried by the signals) to the working memory 1135, from which the processor(s) 1105 retrieves and executes the instructions. The instructions received by the working memory 1135 may optionally be stored on a storage device 1125 either before or after execution by the processor(s) 1110.

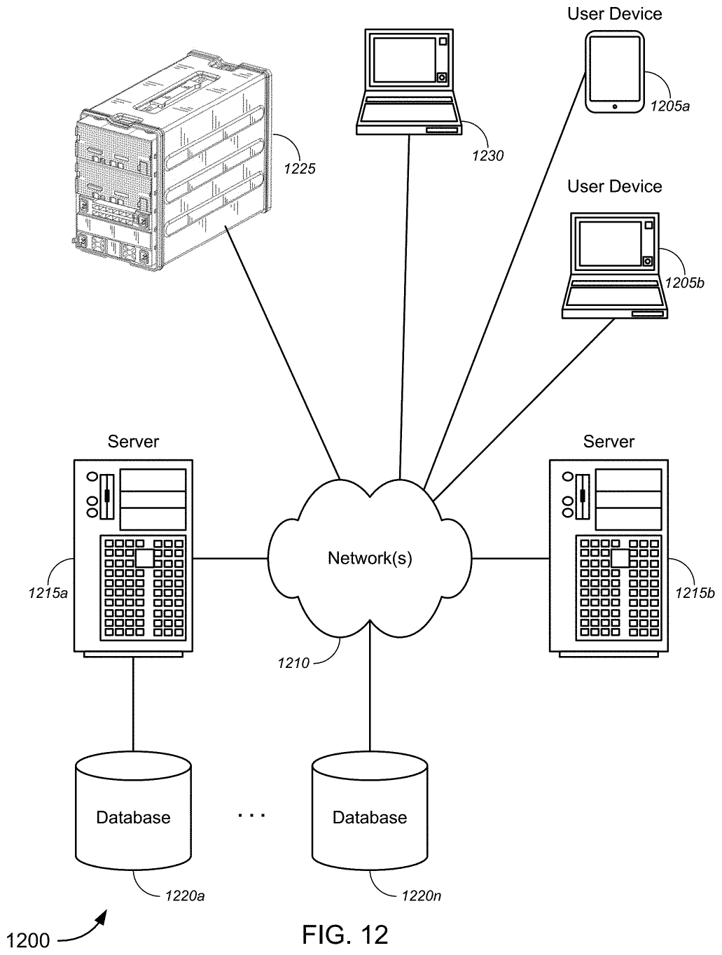

As noted above, a set of embodiments comprises methods and systems for implementing a modular and portable data center, and, in particular embodiments, to methods, systems, and apparatuses for implementing a modular and portable data center that fits within a carry-on suitcase. FIG. 12 illustrates a schematic diagram of a system 1200 that can be used in accordance with one set of embodiments. The system 1200 can include one or more user computers, user devices, or customer devices 1205. A user computer, user device, or customer device 1205 can be a general purpose personal computer (including, merely by way of example, desktop computers, tablet computers, laptop computers, handheld computers, and the like, running any appropriate operating system, several of which are available from vendors such as Apple, Microsoft Corp., and the like), cloud computing devices, a server(s), and/or a workstation computer(s) running any of a variety of commercially-available UNIX™ or UNIX-like operating systems. A user computer, user device, or customer device 1205 can also have any of a variety of applications, including one or more applications configured to perform methods provided by various embodiments (as described above, for example), as well as one or more office applications, database client and/or server applications, and/or web browser applications. Alternatively, a user computer, user device, or customer device 1205 can be any other electronic device, such as a thin-client computer, Internet-enabled mobile telephone, and/or personal digital assistant, capable of communicating via a network (e.g., the network(s) 1210 described below) and/or of displaying and navigating web pages or other types of electronic documents. Although the exemplary system 1200 is shown with two user computers, user devices, or customer devices 1205, any number of user computers, user devices, or customer devices can be supported.

Certain embodiments operate in a networked environment, which can include a network(s) 1210. The network(s) 1210 can be any type of network familiar to those skilled in the art that can support data communications using any of a variety of commercially-available (and/or free or proprietary) protocols, including, without limitation, TCP/IP, SNA™, IPX™, AppleTalk™, and the like. Merely by way of example, the network(s) 1210 can each include a local area network (“LAN”), including, without limitation, a fiber network, an Ethernet network, a Token-Ring™ network, and/or the like; a wide-area network (“WAN”); a wireless wide area network (“WWAN”); a virtual network, such as a virtual private network (“VPN”); the Internet; an intranet; an extranet; a public switched telephone network (“PSTN”); an infra-red network; a wireless network, including, without limitation, a network operating under any of the IEEE 802.11 suite of protocols, the Bluetooth™ protocol known in the art, and/or any other wireless protocol; and/or any combination of these and/or other networks. In a particular embodiment, the network might include an access network of the service provider (e.g., an Internet service provider (“ISP”)). In another embodiment, the network might include a core network of the service provider, and/or the Internet.

Embodiments can also include one or more server computers 1215. Each of the server computers 1215 may be configured with an operating system, including, without limitation, any of those discussed above, as well as any commercially (or freely) available server operating systems. Each of the servers 1215 may also be running one or more applications, which can be configured to provide services to one or more clients 1205 and/or other servers 1215.

Merely by way of example, one of the servers 1215 might be a data server, a web server, a cloud computing device(s), or the like, as described above. The data server might include (or be in communication with) a web server, which can be used, merely by way of example, to process requests for web pages or other electronic documents from user computers 1205. The web server can also run a variety of server applications, including HTTP servers, FTP servers, CGI servers, database servers, Java servers, and the like. In some embodiments of the invention, the web server may be configured to serve web pages that can be operated within a web browser on one or more of the user computers 1205 to perform methods of the invention.

The server computers 1215, in some embodiments, might include one or more application servers, which can be configured with one or more applications accessible by a client running on one or more of the client computers 1205 and/or other servers 1215. Merely by way of example, the server(s) 1215 can be one or more general purpose computers capable of executing programs or scripts in response to the user computers 1205 and/or other servers 1215, including, without limitation, web applications (which might, in some cases, be configured to perform methods provided by various embodiments). Merely by way of example, a web application can be implemented as one or more scripts or programs written in any suitable programming language, such as Java™, C, C #™ or C++, and/or any scripting language, such as Perl, Python, or TCL, as well as combinations of any programming and/or scripting languages. The application server(s) can also include database servers, including, without limitation, those commercially available from Oracle™, Microsoft™, Sybase™ IBM™, and the like, which can process requests from clients (including, depending on the configuration, dedicated database clients, API clients, web browsers, etc.) running on a user computer, user device, or customer device 1205 and/or another server 1215. In some embodiments, an application server can perform one or more of the processes for implementing a modular and portable data center, and, in particular embodiments, to methods, systems, and apparatuses for implementing a modular and portable data center that fits within a carry-on suitcase, as described in detail above. Data provided by an application server may be formatted as one or more web pages (comprising HTML, JavaScript, etc., for example) and/or may be forwarded to a user computer 1205 via a web server (as described above, for example). Similarly, a web server might receive web page requests and/or input data from a user computer 1205 and/or forward the web page requests and/or input data to an application server. In some cases, a web server may be integrated with an application server.

In accordance with further embodiments, one or more servers 1215 can function as a file server and/or can include one or more of the files (e.g., application code, data files, etc.) necessary to implement various disclosed methods, incorporated by an application running on a user computer 1205 and/or another server 1215. Alternatively, as those skilled in the art will appreciate, a file server can include all necessary files, allowing such an application to be invoked remotely by a user computer, user device, or customer device 1205 and/or server 1215.

It should be noted that the functions described with respect to various servers herein (e.g., application server, database server, web server, file server, etc.) can be performed by a single server and/or a plurality of specialized servers, depending on implementation-specific needs and parameters.

In certain embodiments, the system can include one or more databases 1220a-1220n (collectively, “databases 1220”). The location of each of the databases 1220 is discretionary: merely by way of example, a database 1220a might reside on a storage medium local to (and/or resident in) a server 1215a (and/or a user computer, user device, or customer device 1205). Alternatively, a database 1220n can be remote from any or all of the computers 1205, 1215, so long as it can be in communication (e.g., via the network 1210) with one or more of these. In a particular set of embodiments, a database 1220 can reside in a storage-area network (“SAN”) familiar to those skilled in the art. (Likewise, any necessary files for performing the functions attributed to the computers 1205, 1215 can be stored locally on the respective computer and/or remotely, as appropriate.) In one set of embodiments, the database 1220 can be a relational database, such as an Oracle database, that is adapted to store, update, and retrieve data in response to SQL-formatted commands. The database might be controlled and/or maintained by a database server, as described above, for example.

According to some embodiments, system 1200 might further comprise a modular and portable datacenter 1225 (similar to modular and portable data center(s) 100, 200, 400, 500, 600, 700, 800, 900, of FIGS. 1, 2, and 4-9 or the like). System 1200 might further comprise remote device 1230 (similar to remote device 925 of FIG. 9, or the like. The modular and portable datacenter 1225 might be communicatively coupled to other components of system 1200 via network(s) 1210.

In operation, a modular and portable data center 1225 might comprise an external case. The external case might have dimensions that comply with commercial carry-on suitcase minimum dimensions. These dimensions might be 9 inches by 14 inches by 22 inches. The external case might have at least two datacenter grade servers contained within the external case, a fan subassembly contained within the external case to cool the at least two datacenter grade servers contained within the external case, and a power subassembly contained within the external case and configured to provide power to the at least two datacenter grade servers and the fan subassembly.

The at least two datacenter grade servers might each comprise the ability to operate at least 24-core CPUs. The external case might further comprise one or more storage modules for storing at least 512 GB of RAM and at least 8 TB of NVMe storage. The external case might further contain at least one full height, full-length (“FHFL”) double-wide GPU contained within the external case and might also contain at least two half-height, half-length (“HHHL”) PCIe add-in cards contained within the external case.

These and other functions of the system 1200 (and its components) are described in greater detail above with respect to FIGS. 1-10.

While certain features and aspects have been described with respect to exemplary embodiments, one skilled in the art will recognize that numerous modifications are possible. For example, the methods and processes described herein may be implemented using hardware components, software components, and/or any combination thereof. Further, while various methods and processes described herein may be described with respect to particular structural and/or functional components for ease of description, methods provided by various embodiments are not limited to any particular structural and/or functional architecture but instead can be implemented on any suitable hardware, firmware and/or software configuration. Similarly, while certain functionality is ascribed to certain system components, unless the context dictates otherwise, this functionality can be distributed among various other system components in accordance with the several embodiments.

Moreover, while the procedures of the methods and processes described herein are described in a particular order for ease of description, unless the context dictates otherwise, various procedures may be reordered, added, and/or omitted in accordance with various embodiments. Moreover, the procedures described with respect to one method or process may be incorporated within other described methods or processes; likewise, system components described according to a particular structural architecture and/or with respect to one system may be organized in alternative structural architectures and/or incorporated within other described systems. Hence, while various embodiments are described with—or without—certain features for ease of description and to illustrate exemplary aspects of those embodiments, the various components and/or features described herein with respect to a particular embodiment can be substituted, added and/or subtracted from among other described embodiments, unless the context dictates otherwise. Consequently, although several exemplary embodiments are described above, it will be appreciated that the invention is intended to cover all modifications and equivalents within the scope of the following claims.

What is claimed is:

1. An apparatus for providing a modular and portable data center, comprising:
an external case, the external case having a form factor that complies with commercial airline carry-on suitcase dimensions, and the external case comprising:
a plurality of slots configured to hold at least two separate datacenter grade server modules within the external case;
a fan subassembly contained within the external case; and
a power subassembly contained within the external case and configured to provide power to the at least two separate datacenter grade servers and the fan subassembly.

2. The apparatus of claim 1, wherein the form factor that complies with commercial airline carry-on suitcase dimensions has dimensions of 9 inches or less by 14 inches or less by 22 inches or less.

3. The apparatus of claim 1, wherein the external case further comprises a handle attached to an outer surface of the external case and at least one wheel attached to the outer surface of the external case.

4. The apparatus of claim 3, wherein the at least one wheel attached to the outer surface of the external case is removable.

5. The apparatus of claim 1, wherein the external case is water resistant, and wherein the external case is made of at least one of made carbon, metal, plastic, or fabric.

6. The apparatus of claim 1, wherein the external case further comprises the at least two separate datacenter grade server modules held within at least some of the plurality slots.

7. The apparatus of claim 1, wherein the external case further comprises the at least two separate datacenter grade server modules, wherein a first separate datacenter grade server module of the at least two separate datacenter grade server modules has a first size and is contained within a one or more first slots of the plurality of slots, and wherein a second separate datacenter grade server module of the at least two separate datacenter grade server modules has a second height and is contained within one or more second slots of the plurality of slots.

8. The apparatus of claim 6, wherein the at least two separate datacenter grade server modules each comprise an ability to operate at least 24-core central processing units (“CPUs”).

9. The apparatus of claim 1, wherein the external case further comprises an internal case contained within the external case, the internal case comprising:
the plurality of slots defined by one or more mounting brackets, wherein the at least two separate datacenter grade server modules are held within the plurality of slots via the one or more mounting brackets.

10. The apparatus of claim 9, wherein the mounting brackets comprise six axis anti-vibration mounts.

11. The apparatus of claim 1, wherein the power subassembly comprises dual power inputs, each of the dual power inputs providing power to the at least two separate datacenter grade server modules and the fan subassembly.

12. The apparatus of claim 11, wherein each of the dual power inputs are hot swappable.

13. The apparatus of claim 11, wherein each of the dual power inputs provide redundant power for another of the dual power inputs, wherein if one of the dual power inputs fails, another of the dual power inputs continues to provide power to the at least two separate datacenter grade server modules and the fan subassembly.

14. The apparatus of claim 1, wherein the fan subassembly comprises at least two fans.

15. The apparatus of claim 1, wherein the external case further comprises a storage module for storing at least one of 512 gigabytes (“GB”) of random-access memory (“RAM”) or 8 terabytes (“TB”) of non-volatile memory (“NVM”) storage.

16. The apparatus of claim 1, wherein the external case further comprises at least one of a full height, full-length (“FHFL”) double-wide graphics processing unit (“GPU”) contained within the external case or a half-height, half-length (“HEEL”) peripheral component interconnect express (“PCIe”) add-in card.

17. A system, comprising:
a first external case, the first external case having a first form factor that complies with commercial airline carry-on suitcase dimensions, and the first external case comprising:
at least two separate and first datacenter grade server modules contained within the first external case;
a first fan subassembly contained within the first external case; and
a first power subassembly contained within the first external case and configured to provide power to the at least two separate and first datacenter grade server modules and the first fan subassembly.

18. The system of claim 17, further comprising:
a computer external to the first external case and communicatively coupled to the at least two separate and first datacenter grade server modules contained within the first external case.

19. The system of claim 17, further comprising:
a second external case, the second external case having a second form factor that complies with commercial airline carry-on suitcase dimensions, and the second external case comprising:
at least two separate and second datacenter grade server modules contained within the second external case;
a second fan subassembly contained within the second external case; and
a second power subassembly contained within the second external case and configured to provide power to the at least two separate and second datacenter grade server modules and the second fan subassembly.

20. The system of claim 19, wherein the at least two separate and first datacenter grade server modules are communicatively coupled to the at least two separate and second datacenter grade server modules and function as a cluster.
